(19) United States
(12) Patent Application Publication
(10) Pub. No.: US 2024/0030381 A1
(43) Pub. Date: Jan. 25, 2024

(54) Method for Producing a Semiconductor Body and Semicondcutor Arrangement

(71) Applicant: ams-OSRAM International GmbH, Regensburg (DE)

(72) Inventors: Peter Stauss, Regensburg (DE); Adrian Avramescu, Regensburg (DE); Norwin von Malm, Nittendorf (DE)

(21) Appl. No.: 18/044,046

(22) PCT Filed: Oct. 29, 2021
(86) PCT No.: PCT/EP2021/080085

§ 371 Date: Mar. 3, 2023

(30) Foreign Application Priority Data
Oct. 30, 2020 (DE) 10 2020 128 678.3

(51) Int. Cl. H01L 33/16; H01L 33/00

(52) U.S. Cl. CPC H01L 33/16; H01L 33/0062; H01L 33/0093

(57) ABSTRACT

In an embodiment a method for producing a semiconductor body includes providing an auxiliary carrier, depositing a layer sequence on the auxiliary carrier having a first layer including a doped semiconductor material and a second layer including an undoped semiconductor material on the first layer, performing an electrochemical porosification of the first layer, wherein a degree of porosity is at least 20% by volume, forming a functional semiconductor body on the second layer and detaching the semiconductor body from the auxiliary carrier.

This patent application is a national phase filing under section 371 of PCT/EP2021/080085, filed Oct. 29, 2021, which claims the priority of German patent application 10 2020 128 678.3, filed Oct. 30, 2021, each of which is incorporated herein by reference in its entirety.

### TECHNICAL FIELD

The present invention relates to a method for producing a semiconductor body, in particular an optoelectronic component. The invention likewise relates to a semiconductor body, in particular an optoelectronic component.

### BACKGROUND

During the production of semiconductor components it is often necessary to rebond the partly completed semiconductor layer stack, i.e. to transfer it from a first carrier to a second carrier. Precisely in the case of thin-film components, this may pose difficulties owing to the risk of fragility and requires an increased outlay.

By way of example, in the case of GaN-based thin-film components, the GaN epitaxial layer has to be separated from the semiconductor substrate forming the component. An LLO (laser lift-off) method, inter alia, can be used for this purpose. In that method, the epitaxially grown GaN boundary layer with respect to the (sapphire) substrate is decomposed by laser irradiation with a suitable wavelength. Various problems may occur during such a process. Firstly, a high-power density is necessary for a laser lift-off in order to vaporize the epitaxial GaN boundary layer. As a result, the epitaxial layers that follow may be damaged and thus at least influence the electronic structure of the active region. In order to prevent this, the buffer layers are correspondingly thicker.

In addition, by virtue of the optically limited focusing of the laser beam through the sapphire substrate, it may be difficult, depending on the application, to selectively detach very small individual pre-structured chips by means of the laser without likewise influencing, damaging or inadvertently detaching the neighboring chip. This problem is applicable especially to optoelectronic components having small dimensions of a few μm to a few 10 μm, so-called μ-LEDs (edge length of <20 μm or <10 μm or <5 μm), if they are transferred to a receiver substrate (backplane) directly by LLO.

On the other hand, in the case of specific products having very large chips (edge length of 4-10 mm), the carrier substrate, for example the sapphire carrier, is detached by way of the individual LLO only after the mounting of the chips in the component. Since it is necessary in that case to introduce a high-power density over the entire chip, there is an increased risk of fracture for the chip. If the optical material contrast or else the thermal contrast between substrate and epitaxial layer is not sufficient (such as e.g. in the case of homoepitaxy of InGaN on GaN wafers), the LLO process is not a practicable solution.

### SUMMARY

Embodiments provide a method in which the holding force between the sapphire substrate and the layers which are part of the component is reduced. As a result, a simpler detachment is attained, for example by a laser lift-off but also by means of mechanical methods, e.g. stamping processes or the like.

Embodiments provide a method for processing a semiconductor body which provides a first step of providing an auxiliary carrier. This is followed by depositing a layer sequence on the carrier having a first layer comprising a doped semiconductor material, in particular a III_V semiconductor material, and also a second layer comprising an undoped semiconductor material on the first layer. The first layer is electrochemically porosified in a subsequent step, wherein a degree of porosity is at least 20% by volume. A degree of porosity can likewise be between 50% by volume and 90% by volume. A semiconductor component, and in particular an active semiconductor body suitable for emitting light, is formed on the second layer. Finally, the semiconductor body is detached from the auxiliary carrier.

In this context, a lattice constant is understood to mean the length of a unit cell in a defined material system. In this case, the material system is homogeneous and does not contain any defects or lattice defects. It is thus unstrained. The lattice constant is a characteristic variable for any material system and, relative to the unstrained material system, is also referred to as a specific lattice constant. Different material systems may accordingly have a different specific lattice constant, as is shown in the above link. Therefore, if material systems having different lattice constants are combined, a strain arises in a boundary region of these systems, i.e. the lattice constants change. This change decreases with increasing distance from the boundary region. Moreover, excessively large differences in the lattice constants can result in imperfections or defects. The proposed method and also the implementations according to the invention can exploit this effect in a targeted manner.

Hereinafter, a functional semiconductor layer sequence or a functional semiconductor body denotes a layer sequence which is structured in such a way that it can perform an electrical function as a finished component. In this case, a functional semiconductor layer sequence can be singulated, each individual element then having the desired functionality. One example of a functional semiconductor layer sequence would be a layer sequence comprising a region suitable for emitting light, for example. Another example would be an npn junction having a transistor function. The layer sequence can also combine a plurality of functions with one another.

An auxiliary carrier is a carrier composed of an inert material which serves as a basis for later methods, in particular epitaxial deposition of semiconductor materials. An example of a material for an auxiliary carrier is sapphire (Al₂O₃), but also silicon nitrite or some other material. It may be expedient for the material to be inert with respect to various etching processes that are used in the production of semiconductor components. In some cases, the auxiliary carrier remains on the component and becomes part thereof. In this case, the auxiliary carrier is also referred to simply as carrier substrate. In other cases, a component produced on the auxiliary carrier is detached (as set out further below).

A semiconductor material is generally understood to mean an undoped compound semiconductor material, unless explicitly stated otherwise. The term “undoped” in this case means that a dedicated, deliberate and intentional doping with a different element or material is not performed. Defects or impurities that are always present in practice do not come under doping within the meaning of this application. A compound semiconductor material is a combination of two, 3 or more elements that are produced in a crystal structure, so as to form an electronic band structure, and the resultant element has electrical semiconductor properties. A typical compound semiconductor is a so-called III-V compound semiconductor consisting of one or more elements from the fifth main group and one or more elements from the third main group. Examples of compound semiconductor material are GaAs, AlGaAs, GaN, AlGaN, InGaP InGaN, GaP, AlGaP, AlInGaN, and others mentioned here.

A doped semiconductor is a semiconductor material into which a dopant is introduced. Depending on the desired doping, in the case of a III-V compound semiconductor, the dopant may be Si, Te, Se, Ge for an n-type doping and for example Mg for a p-type doping. Further dopants are presented in this application. The dopant is introduced during an epitaxial deposition of the III-V compound semiconductor material, but the doping can also be effected subsequently by various methods. The doping concentration is a few orders of magnitude lower than the concentration of the atoms in the starting material or base material. For example, the concentration is in the range of 1*10¹⁷ doping atoms/cm³ to 1*10²¹ doping atoms/cm³.

Electrochemical decomposition or electrochemical etching is a process in which a semiconductor material is broken down with the aid of an electrical voltage and current. This enables a layer of a semiconductor material to be broken down or etched. However, this process does not proceed uniformly, but rather nonuniformly, e.g. on account of dislocations or material defects. This can be exploited given a suitable choice of parameters, e.g. applied voltage and concentration of a dopant and of the semiconductor material to be etched. In this regard, for example, a different speed and also porosity of the material to be etched can be achieved. The term electrochemical porosification is thus understood to mean an electrochemical process that leaches material selectively from a body so as to leave a porous or sponge like structure. A porosified semiconductor body or a semiconductor layer thus produces a network structure similar to a sponge or a bone that has sufficient mechanical stability with at the same time low mass or material volume. A layer can be subjected to a selective porosification process in which a structured mask is applied before the process. Said mask reduces or prevents a current flow in regions of the layer on account of so-called shading, such that no or only very little porosification takes place in regions over which a mask is arranged. Correspondingly, a non-porosified semiconductor body does not exhibit a mesh- or sponge-like structure, even though it may nevertheless have various defects or lattice defects. Moreover, in some implementations, there may be effects in the boundary region in which a section of an intrinsically non-porosified region exhibits slight porosification, in particular at the edges of such a region, in which case the so-called degree of porosity (see further below) decreases with increasing distance from the edges.

In the case of a non-porosified region, penetration of an electrolyte during the electrochemical etching process under the shaded regions is made more difficult or likewise prevented, such that no further etching channels can form there, or existing channels are not widened by the electrolyte. As a result, the removal rate is distinctly lower under the shaded regions, such that the material is porosified there to a much lesser degree, if at all.

The term degree of porosity describes the ratio of material volume to the total volume of the layer. A degree of porosity in the region of 20% thus means that 20% of material has been removed by comparison with the original volume. In the case of a degree of porosity of 90%, 90% of the material has been leached out by the electrochemical deposition process, and only 10% of the material remains.

The inventors have recognized that the adhesion of the material of the first layer to the auxiliary carrier or to the second layer is crucially reduced by the electrochemical process and the leaching out of material, such that distinctly less force or energy expenditure is necessary in order to break the bond. A laser lift-off process, for example, can be simplified as a result because a lower intensity of the laser is necessary. Moreover, it has been recognized that absorption of the laser light does not change significantly despite the porosity, and so the energy deposition still takes place substantially at the interface at which the breaking is intended to take place.

Overall, therefore, the various detachment methods become simpler, and the risk of fracture or the risk of damage of the component or components decreases.

It has furthermore been established that the second undoped layer is not removed by the electrochemical etching process, or is removed thereby to a distinctly lesser extent than the doped first layer. Si, inter alia, is suitable as doping, the etching or detachment rate being dependent on the concentration of the dopant and also the applied electrical voltage.

In one aspect, the first layer comprises a doped semiconductor material. At least one of the following semiconductor materials, inter alia, is appropriate as base or basic material; GaN, GaP, GaAs, AlGaN, InGaN, AlInGaN, AlInGaP, GaAs, AlGaAs and AlGaP. In some aspects, the doped semiconductor material and the undoped semiconductor material can comprise the same base semiconductor material. During the epitaxial deposition of the first layer, the latter can be provided with a dopant. The dopant can comprise Si, C, Se, Te, Sn, Ge or Mg with a concentration in the range of 1*10¹⁷ atoms/cm³ to 1*10²¹ atoms/cm³. As a result of the doping of the first layer, the electrochemical etching process takes place more rapidly in the first layer. To put it more generally, the method in some aspects provides for choosing a material of the first and second layers such that an electrochemical porosification takes place more rapidly in the first layer than in the second layer.

In addition, it is possible to provide one or more buffer layers between the auxiliary carrier and the first layer, e.g. for the purpose of planarization or else lattice mismatch. Said layers can likewise be removed during the electrochemical etching process, or alternatively remain on the auxiliary carrier. In some examples, a thickness of the first layer can be in the range of 100 nm to 4000 nm, in particular in the range of 100 nm to 1000 nm. In some implementations, the second layer is in the range of 10 nm to 300 nm, in particular in the range of 50 nm to 200 nm.

A further aspect is concerned with forming an active semiconductor body suitable for emitting light. Accordingly, it is possible to apply a third semiconductor layer on the second layer, in which at least one active layer configured for emitting light is formed. Contact regions are then formed on the third semiconductor layer, which contact regions contact the active layer formed for emitting light. This step is optional, can be omitted or else can be adapted to the design. By way of example, just one contact region can be formed.

In some aspects, it is provided that after detaching the semiconductor body from the auxiliary carrier, the porosified first layer remains on the functional semiconductor body, and is optionally embodied as an output coupling structure for electromagnetic radiation. As a result, the porosified layer can continue to be used functionally.

Another step relates to a method in which ridges, pedestals or other holding structures additionally remain even after porosification. In one example, depositing a first layer sequence comprises applying a structured dielectric mask on the second layer for the selective porosification of the first layer. The structured mask is then removed after the step of electrochemical porosification. As a result of the structuring by means of a nonconductive mask on the second layer, regions in the first layer are shaded by the mask. As a result, during the electrochemical etching process, no current can flow through the shaded regions, or the resistance in these regions changes. Likewise, penetration of an electrolyte during the electrochemical etching process under the shaded regions is made more difficult or likewise prevented, such that no further etching channels can form there, or existing channels are not widened by the electrolyte. As a result, the removal rate is distinctly lower under the shaded regions, such that the material is porosified there to a much lesser degree, if at all.

In one aspect, consideration is given here to choosing the structure dimension of the mask to be at least equal in magnitude to that of the desired structured formed in the first layer after the electrochemical porosification. In other words, in some aspects, with regard to dimensioning, the mask should be chosen to be somewhat larger than the dimension of the desired structure in order to compensate for the existing undercutting caused by the process. For nitrides, the undercut can be in the range of 200 nm to approximately 800 nm; for materials based on GaAs or GaP, the undercut can even be greater than 1000 nm. The dimension and lateral extent must be chosen accordingly.

In some aspects, after the electrochemical porosification, the mask is removed and then a third semiconductor layer is applied on the second layer, in which at least one active layer configured for emitting light is formed. Optionally, it is possible to form one or more contact regions on the third semiconductor layer, which contacts the active layer formed for emitting light.

Depending on the design, before or after the step above, it is possible to remove regions between non-porosified structures in the first layer, in particular by structured etching, thus giving rise to a semiconductor body suitable for emitting light over a non-porosified structure.

In this way, it is possible to singulate semiconductor structures which stand on a holding structure, which are formed by the non-porosified regions. In this case, the porosified regions of the first layer can be removed by selective etching. The remaining non-porosified regions are distinguished by a lower holding force on account of their small area and thus form a pedestal-type holding structure in some implementations. Said holding structure exhibits a smaller area than the area occupied by the semiconductor structure (in plan view). In some aspects, the holding structure can form a truncated cone or a trapezoid, the smaller base area of this body being connected to the component.

In some examples, the removing, in particular by structured etching of regions between non-porosified structures, is performed in such a way that material is removed as far as the carrier.

Finally, detaching the semiconductor body from the auxiliary carrier can comprise detaching the semiconductor body suitable for emitting light from the non-porosified structure of the first layer.

A further aspect relates to a semiconductor arrangement, having a carrier substrate, and also a first layer arranged on the carrier substrate and having at least one first region and also at least one second region. A second layer is arranged on the first layer and a functional semiconductor layer sequence is arranged on the second layer. The proposed principle provides for the at least one first region of the first layer to comprise a porosified semiconductor material having a degree of porosity of at least 20% by volume, and for the at least one second region of the first layer to substantially have a degree of porosity of less than 10% by volume, in particular less than 5% by volume, and also to comprise a doped semiconductor material.

Alternatively, a semiconductor arrangement can be provided which comprises a carrier substrate and also a first layer arranged on the carrier substrate. A second layer is arranged on the first layer and a functional semiconductor layer sequence is arranged on the second layer. The proposed principle provides for the first layer to be porosified in particular areally, the degree of porosity comprising at least 20% by volume.

In order to ensure the porosification, in one aspect, the second layer is formed with a doping different than that of the at least one second region of the first layer. In particular, the second layer can have no doping, i.e. can be undoped.

In some aspects, the functional semiconductor layer sequence can comprise an active semiconductor layer sequence suitable for emitting light, wherein at least one contact region for contacting is provided on the side of the layer sequence facing away from the second and first layers.

In one implementation, the functional semiconductor layer sequence is formed with at least one trench which separates regions of the functional semiconductor layer sequence from one another. Each portion separated in this way inherently forms a functional semiconductor body and is arranged over a second region of the first layer.

### BRIEF DESCRIPTION OF THE FIGURES

Further aspects and embodiments according to the proposed principle will be disclosed in relation to the various embodiments and examples that are described in detail in association with the accompanying drawings. In the figures:

FIG. 1 shows several steps of a method for producing a functional semiconductor body which realize some aspects of the proposed principle;

FIGS. 2A and 2B show a further exemplary embodiment with several method steps for producing a functional semiconductor body which realize some aspects of the proposed principle;

FIG. 3 shows a configuration of a layer sequence with an additional separating layer according to some aspects of the proposed principle; and

FIGS. 4A to 4C show aspects of a method for producing a semiconductor body with some aspects of the proposed principle.

### DETAILED DESCRIPTION OF ILLUSTRATIVE EMBODIMENTS

The following embodiments and examples show various aspects and combinations thereof according to the proposed principle. The embodiments and examples are not always true to scale. Various elements may likewise be illustrated in enlarged or reduced fashion in order to emphasize individual aspects. It goes without saying that the individual aspects and features of the embodiments and examples shown in the figures can be combined straightforwardly with one another without this adversely affecting the principle according to the invention. Some aspects have a regular structure or shape. It should be noted that slight deviations from the ideal shape may occur in practice, but without being contrary to the inventive concept.

Moreover, the individual figures, features and aspects are not necessarily illustrated in the correct size, and the proportions between the individual elements also need not be fundamentally correct. Some aspects and features are emphasized by being illustrated in enlarged fashion. Terms such as “top”, “above”, “bottom”, “below”, “larger”, “smaller” and the like are, however, represented correctly in relation to the elements in the figures. In this regard, it is possible to infer such relationships between the elements on the basis of the figures.

The inventors have recognized that the partial electrochemical decomposition (called porosification here) of a defined GaN-containing layer causes a great reduction of a holding force between a GaN-epitaxial stack and the epitaxy substrate (sapphire or else Si, GaN). In this case, very uniform pores (in the range of 20 nm to 100 nm) are etched—with homogeneous distribution—into the specific GaN layer. The selectivity of the “porosification” can be achieved by way of a high n-doped doping of the GaN layer with Si, for example. That is to say only sufficiently highly doped layers are porosified.

Since a chemical etching attack takes place over the entire surface area via the vertical through-substance displacement in the GaN epitaxial stack, a “porosification” can take place over the entire wafer. In this case, the layer to be porosified may be buried under other GaN layers.

As an alternative thereto, partial passivation of the surface in “porosification” can result in a laterally selective etching attack. By means of a mask applied, the buried regions in the first layer to be porosified beneath the masked surface regions are not porosified or are only slightly porosified, or etched, laterally in the plane, such that these have different chemical and mechanical properties in subsequent process steps. Optionally, one or more additional second layers can be inserted between the first layer to be porosified and the further layers forming the semiconductor component, such that these additional second layers can serve as a mechanical fracture site in a further process step.

The inventors have recognized that the ratio of porosified area to non-porosified area is of importance for detaching the component from the carrier without damage. It was recognized at the same time that the mechanical stability is larger maintained even in the case of relatively great porosification, and so this ratio can be greater than 2 and even greater than 5.

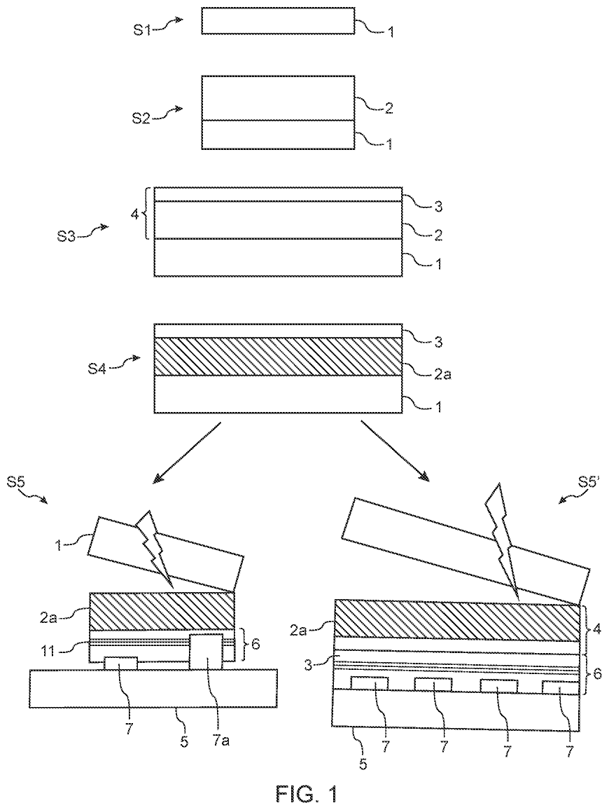

FIG. 1 shows an exemplary first configuration of a method according to the proposed principle for producing a semiconductor body which can be removed from a carrier particularly simply by means of a porous separating layer.

For this purpose, a first step S1 involves providing a carrier substrate 1 as auxiliary carrier. In the present embodiments, this substrate is a sapphire carrier substrate, but a carrier substrate with a different material system can also be used. By way of example, silicon-based, silicon-nitrite-based or, as illustrated, sapphire-based carrier substrates are appropriate. In this case, the auxiliary carrier is also selected inter alia according to the material system used later.

In a next step S2, a first layer 2 of the layer sequence 4 is applied on the auxiliary carrier 1. Said first layer 2 is additionally provided with a dopant during epitaxial growth on the substrate of the auxiliary carrier 1. In the present exemplary embodiment, the material used for the first layer is GaN, which is grown epitaxially with silicon Si as dopant on the auxiliary carrier 1. In this case, the doping concentration of the silicon atoms is in the range of 10×10¹⁸ atoms/cm³. In addition, before the epitaxial growth of the GaN layer 2, it is also possible to apply one or more buffer layers on the material of the auxiliary carrier 1. These layers are not illustrated separately in step S2, but can be used for the further planarization of the auxiliary carrier 1 or else for later current spreading for the electrochemical process. Furthermore, the additional buffer layers also serve as an etch stop or lattice matching structure, depending on the material system used.

In a subsequent step S3, an undoped GaN layer 3 is applied on the doped, epitaxially grown GaN layer 2. With regard to its dimension, the undoped GaN layer is made significantly thinner than the doped GaN layer 2 and, in comparison therewith, also exhibits different mechanical, chemical and electrical properties. The undoped GaN layer 3 and the doped GaN layer 2 jointly form the layer sequence 4.

In step S4, the wafer thus produced is then subjected to an electrochemical breakdown process. The latter is also referred to as a porosifying process or porosification process. For this purpose, a voltage is applied to the wafer structure formed and to the layer sequence 4, such that a current flow takes place through the undoped GaN layer 3 and the doped GaN layer 2. The current flow causes a partial chemical decomposition or breakdown of the doped GaN layer. This process is referred to as porosification. In this case, pores having a size in the range of a few 10 nm to 100 nm are etched uniformly in the doped GaN layer 2 as a result of the electrochemical process. It has been established that the distribution of the pores is substantially homogeneous. The etching rate and also the pore size and the material removal associated therewith are dependent on the applied voltage, the current flow during the electrochemical process and also a concentration of the doping atoms in the GaN layer 2. It should be noted here that, in principle, the undoped GaN layer 3 is also attacked by the electrochemical process. Material is removed in both layers since they are not electrically insulating. However, the conductivity of the undoped GaN layer is distinctly lower, and so the doping with silicon in the layer 2 results in a selectivity during the porosification process.

In other words, during the electrochemical process, the doped GaN layer 2 is attacked and etched, with material being leached out, to a distinctly greater degree than is the case in the undoped GaN layer 3. Since the current is introduced over the entire area of the wafer during the porosification in the present example, the electrochemical process ensues in the layer stack 4 across the entire surface area. The layer 2a porosified in this way in step S4 is thus buried under the non-doped GaN layer 3.

The amount of material removed here by the porosification is adjustable byway of the duration and the parameters described further above. In order to ensure a good detachment later by means of a laser lift-off or some other mechanical method, the inventors proposed a degree of porosity of at least 20% by volume. It has been established here that up to a degree of porosity of approximately 90% by volume to 95% by volume, a mechanical stability of the material left behind is nevertheless sufficient to enable the further production steps. However, the high level of material removal greatly reduces an adhesion between the carrier 1 and the porosified GaN layer 2a or between the latter and the undoped GaN layer 3. In this respect, therefore, a degree of porosity of between 40% by volume and 90% by volume is regarded as expedient.

Following a porosification of the first layer 2 of the layer sequence 4, the wafer produced in this way can be processed further and a functional semiconductor body can be formed thereon. In this case, various production methods and designs of the respective semiconductor bodies are conceivable and known in part to a person skilled in the art.

Steps S5 and S5′ show 2 different examples in this respect, in which a functional semiconductor body is formed as a functional layer sequence 6. The latter comprises a multiple quantum well 11 formed for emitting light of a predefined wavelength during operation. In addition, two contact regions 7 and 7a are provided for the contacting of said multiple quantum well 11 in the functional layer sequence 6. The contact region 7a extends through the multiple quantum well 11 and contacts the buried doped layer between the porosified layer 2a and the multiple quantum well 11. The other contact region 7 contacts the opposite layer of the functional layer sequence 6 in relation to the multiple quantum well 11.

A similar embodiment is illustrated in step S5′, here the respective contact regions 7 merely being recessed in the layer. Other elements can also be used besides the 4 contact regions illustrated.

So-called “rebonding” or “transferring” to a carrier 5 is performed during this production process. For this purpose, after the production of the layer sequence 6 and optionally the contact regions 7 and 7a, an additional carrier 5 is provided, which is connected to the contact regions 7 and 7a or else the layer sequence 6 (as illustrated in step S5′). The auxiliary carrier 1 can then be removed with the aid of a laser lift-off method. For this purpose, laser light is radiated through the auxiliary carrier 1, and is absorbed in the porosified doped GaN layer 2a and greatly heats the latter. The resultant energy input allows the carrier 1 to be separated from the porosified layer 2a and thus removed.

The modification of the boundary layer toward the auxiliary carrier 1 makes possible a laser lift-off method with a comparatively low laser power. As a result, the damage in the auxiliary carrier also decreases, and so said auxiliary carrier is reusable, if appropriate. Reuse of the auxiliary carrier makes it possible to further the costs during the production of such semiconductor components. In addition, by virtue of the reduced adhesion, a laser lift-off is possible and advantageous even in the case of large chips since a stress-reduced lift-off process for the semiconductor components should be possible here as well. Detachment of the entire auxiliary carrier by means of a laser lift-off or else by means of a mechanical or chemical method is thus distinctly facilitated by the porosification and can take place with little energy input even in the case of a small material contrast vertically in a very spatially selective manner as well.

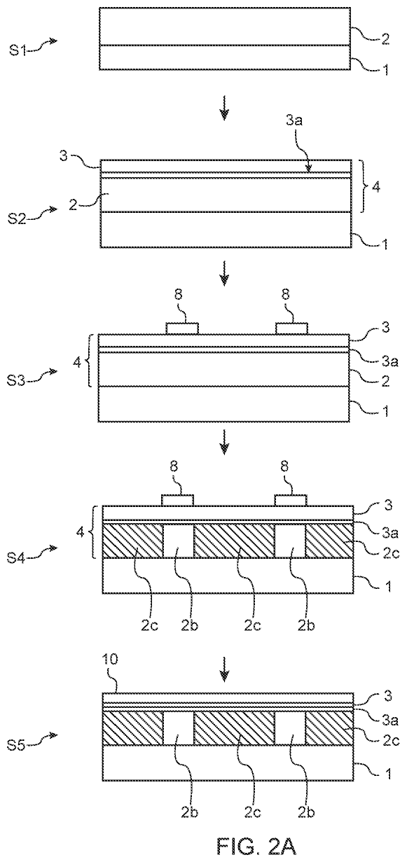

FIGS. 2A and 2B show various steps of a further configuration of the proposed principle, in which additional measures and a structuring of the layer sequence 4 are performed. Further applications can be realized as a result.

In step S1, in this exemplary embodiment, after providing an auxiliary carrier 1, once again a doped GaN layer 2 is grown epitaxially on the auxiliary carrier 1. On the doped GaN layer 2, a thin predetermined breaking or separating layer 3a is then additionally deposited. The latter can be formed for example from AlGaInN or else from intrinsic silicon nitrite, SiN (approximately one monolayer), and likewise extends over the complete wafer in the present exemplary embodiment. The undoped GaN layer 3 is in turn applied over the thin predetermined breaking layer 3a. The resulting layer sequence 4 on the carrier substrate 1 is illustrated in step S2.

In step S3, a structured mask 8 is then applied by way of example at two locations on the undoped GaN layer 3. The mask 8 is chemically inert with respect to the subsequent electrochemical porosification step and is constructed as a hard mask, for example. As illustrated in step S4, after applying the structured mask 8, the electrochemical porosification is carried out. In this case, however, the structure of the mask 8 has a shading effect, such that regions beneath the mask 8 in the first layer 2a are not actually porosified or etched, but rather remain as non-porosified regions 2b. In the example in steps S3 and S4, these regions are two regions which have a width of a few μm and substantially form squares in plan view. However, other dimensions and/or a different number of such regions can also be provided. The shape can likewise be designed differently, for example as polygons or else as circles or rectangles.

The background for such a selective porosification is the fact that a current flow through the layer 3, the layer 3a and the first layer 2 is largely prevented on account of the insulating behavior of the mask 8. In other words, the current always seeks the path of least resistance and would therefore not flow beneath the regions covered or shaded by the mask 8 during the electrochemical process. As a result, a porosification takes place owing to the current flow primarily in the non-shaded regions of the first layer, such that porosified regions 2c form there.

The dimension of the mask 8 is adapted to the dimension of the later non-porosified regions 2b. Although the sheet resistance beneath the mask is greater and the current flow there is significantly smaller, slight undercutting nevertheless takes place to a small extent in the edge region. Owing to the undercutting during the electrochemical porosification, it is expedient for the dimension of the resist mask 8 to be made somewhat larger than the later non-porosified region should be. Slight undercutting beneath the mask and thus into the shaded region is compensated for as a result.

The result of such a selective porosification process is illustrated by way of example in step S5. In this case, the structured resist mask created a plurality of non-porosified regions 2b in the first layer 2, which are bordered by porosified regions 2c in each case. The non-porosified regions 2b are formed in substantially square fashion here in plan view (not illustrated here) and are completely surrounded by porosified regions 2c. After the removal of the resist mask 8, the first n-doped layer 10 of the functional layer sequence 6 is then applied to the undoped GaN layer 3. Said first layer can comprise GaN or some other material system, e.g. InGaN. In this exemplary embodiment, the layer 10 is n-doped. This is not necessary, however; it is also possible to use a different doping or no doping.

During step S6 in FIG. 2B, further epitaxial deposition processes are effected in order to form a multiple quantum well 11 and also a p-doped layer 12. An optically active semiconductor body suitable for emitting light is thus formed on the layer sequence 4. After forming the functional layer sequence 6 and thus the functional semiconductor body, a structured mask having a plurality of structure elements 8a is in turn applied on the surface of the p-doped layer 12. As illustrated in FIG. 2B for a step S6, in this case the mask material is deposited over the non-porosified regions 2b of the second layer 2.

Afterward, in step S7, the structure thus formed is subjected to a selective etching process, such that the non-covered regions of the functional layer sequence and the porosified non-covered regions of the first layer 2 are selectively etched. A selective etch of the layer sequence 6 and of the layer 2 can be effected wet-chemically, but also by means of gaseous etching. Dry etching methods are also conceivable for relatively small etches.

The etching process forms trenches extending from the surface of the layer 12 down to the substrate of the auxiliary carrier 1. The result of such a selective etching process is illustrated in step S7. After the removal of the mask structure 8a, contact regions 7 and 7a can additionally be applied on the surface of p-doped layer 12. In this case, the contact regions 7a are electrically isolated from the p-doped layer 12 and extend through the p-doped layer 12, the multiple quantum well 11 right into the n-doped layer 10. The contact regions 7 directly contact the p-doped layer 12.

As a result of the selective etching and formation of the mesa structure and the trenches 20 in the preceding steps, it is now possible to reach the buried porosified regions 2c in the layer 2 in a simple manner. These regions are wet-chemically selectively removed in a subsequent step, for example by means of a lateral etching attack. After removal by means of an etching process, the non-porosified regions remain as column or pedestal structures. They thus form holding structures 20b, on which the separated semiconductor bodies 60 are arranged. The holding structures 20b with the semiconductor bodies 60 are illustrated here as the result in step S8. In this case, their surface facing the layer sequence 6 is smaller than the side facing the carrier, such that the pedestal structures also form a truncated cone, a truncated pyramid or a trapezoid besides a column-like shape. As a result of the smaller bearing surface compared with the surface toward the carrier, the holding force is reduced further. This decrease in the diameter or, to put it more generally, an alteration of the diameter is achieved by means of a varying doping during the epitaxial deposition of the first layer. The doping also controls the rate of the porosification, inter alia, such that the undercutting under the shaded regions is influenced as well.

In step S9, these semiconductor bodies can then be selectively gripped by means of a stamping die 30 and separated from the holding structures 20b by way of a laser lift-off or a mechanical method (for example by means of a stamping die). The predetermined separating layer 3a may be damaged in the process, but without that adversely affecting the functionality of the components. Depending on the configuration, the predetermined separating layer 3a is constructed as a sacrificial layer. Alternatively, the layer 3a can also be chemically roughened (if that did not already happen as a result of the preceding etching step for removing the regions 2c), such that the light can couple out through this surface particularly well during operation.

Various variations of the proposed principle, i.e. of a porosification of a first layer of a layer sequence, are then possible depending on the application.

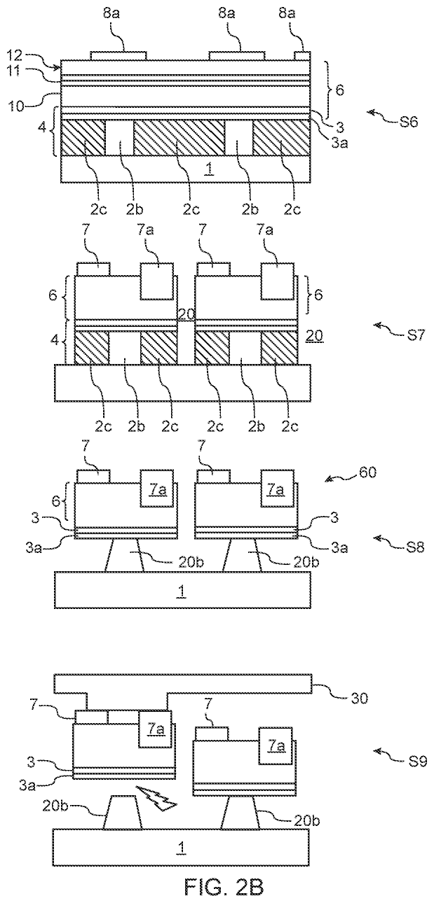

FIG. 3 shows one such example in which differently doped regions for producing different degrees of porosity are proposed. In this case, FIG. 3 shows the result of the first steps of a process for producing a semiconductor component. In this case, a first layer 2 was applied epitaxially on an auxiliary carrier 1, said first layer comprising a region 2′, adjacent to the auxiliary carrier 1, and also a region 2″. The regions 2′ and 2″ are separated from one another by a thin separating layer 3b. The separating layer 3b firstly serves as a predetermined breaking location and comprises AlGaInN or silicon nitride, SiN. Furthermore, the layer 3b separates different doping concentrations from one another. In this regard, the degree of doping of the regions 2 and 2″ is different, and so different degrees of porosity are thus achieved as well during a later electrochemical process. In the present exemplary embodiment, the doping is chosen to be distinctly higher in the region 2′ than in the region 2″. As a result, during the electrochemical process, distinctly more material is removed and decomposed in the region 2′ than in the region 2″ located closer to the undoped GaN layer 3.

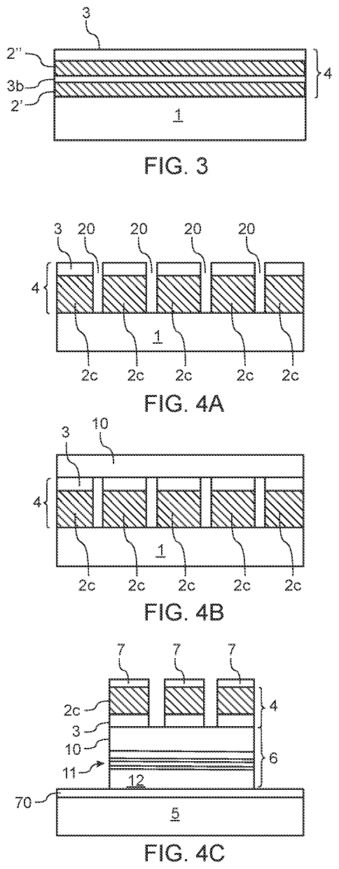

The structure thus produced is primarily suitable as an output coupling structure, for example. After forming a functional semiconductor body configured for emitting light, the auxiliary carrier is separated from the material 2′ and the separating layer 3b. For this purpose, in a further step, the predetermined breaking location 3b can also be removed, such that only the porosified region 2″ of the first layer remains on the component. The degree of porosity of this porosified layer is chosen such that the layer 2″ serves as an output coupling structure since the pore structure thereof forms a suitable refractive index jump. A subsequent toughening by means of KOH or other measures is accordingly unnecessary. Such a doping profile or, to put it more generally, a doping profile that changes across the layer enables a further variation during detachment. By way of example, it is possible to choose the doping profile so as to increase in a direction across the layer profile 6. If a selective porosification is then performed, as is carried out in the example in FIG. 2, the structures shown in FIG. 2 can be created by the undercutting, in the case of which structures the cross-section changes and becomes smaller for example in a direction toward the layer sequence 6. FIGS. 4A to 4C show further exemplary embodiments of a processing and production of a semiconductor body according to the proposed principle. In FIG. 4A, for example, after a porosification of the first layer 2, a mesa structure was introduced into the layer sequence 4, having a multiplicity of trenches 20 arranged at periodic distances. The layer sequence 4 is subsequently covered with a planarization layer 10 composed of InGaN. In this case, the thickness of the trenches 20 is chosen such that the InGaN layer is not filled into the trenches, but rather forms bridges, such that the trenches substantially remain as cavities in the structure thus formed. Furthermore, the adhesion between the substrate of the auxiliary carrier 1 and the porosified regions 2c of the first layer 2 decreases as a result.

After forming a functional semiconductor body and a layer sequence 6 illustrated in FIG. 4C, the resultant component is transferred and separated from the carrier substrate 1. By way of its p-doped layer 12, the functional layer sequence 6 is then connected to a metallic p-type contact 70 and arranged on a carrier 100. Further metallic contacts 7 can be applied on the porosified regions 2c of the layer sequence 4. It is thus possible for example to selectively control individual regions of the functional layer 6 and thus for example to adjust the intensity of light emission. Moreover, here as well the porosified regions 2c can serve as an output coupling structure.

In the implementations illustrated, the thickness of the first layer is in the range of 100 nm to 2000 nm. It is preferably in the range of 500 nm to 1000 nm. The covering layer 10 of the functional layer sequence can be in the range of 50 nm to 200 nm before further growth.

1.-21. (canceled)

22. A method for producing a semiconductor body, the method comprising:
providing an auxiliary carrier;
depositing a layer sequence on the auxiliary carrier having a first layer comprising a doped semiconductor material and a second layer comprising an undoped semiconductor material on the first layer;
performing an electrochemical porosification of the first layer, wherein a degree of porosity is at least 20% by volume;
forming a functional semiconductor body on the second layer; and
detaching the semiconductor body from the auxiliary carrier.

23. The method as claimed in claim 22,
wherein the first layer comprises at least GaN, GaP, AlGaN, InGaN, AlInGaN, AlInGaP or AlGaAs, and
wherein the first layer is provided with a dopant during an epitaxial deposition.

24. The method as claimed in claim 23, wherein the dopant comprises at least S1, Ge, Te, Se, Mg, Zn, C or Be with a concentration in a range of 1*10¹⁷ 1/cm³ to 1*10²¹ 1/cm³.

25. The method as claimed in claim 22, wherein the doped semiconductor material and the undoped semiconductor material have the same base semiconductor material.

26. The method as claimed in claim 22, wherein a material of the first and second layers is chosen such that the electrochemical porosification takes place more rapidly in the first layer than in the second layer.

27. The method as claimed in claim 22, wherein a thickness of the first layer is in a range of 100 nm to 4000 nm, and/or wherein a thickness of the second layer is in a range of 10 nm to 300 nm.

28. The method as claimed in claim 22, wherein forming the functional semiconductor body comprises:
applying a third semiconductor layer on the second layer, in which at least one active layer for emitting light is formed, and
forming contact regions on the third semiconductor layer, which contact the active layer formed for emitting light.

29. The method as claimed in claim 22, wherein, after detaching the semiconductor body from the auxiliary carrier, the porosified first layer remains on the functional semiconductor body, and is optionally an output coupling structure for electromagnetic radiation.

30. The method as claimed in claim 22, wherein depositing the first layer comprises:
applying a structured mask on the second layer for performing a selective porosification of the first layer,
removing the structured mask after electrochemical porosification.

31. The method as claimed in claim 30, wherein the structured mask has structure dimensions which are at least equal in magnitude to dimensions of a non-porosified structure formed in the first layer after the electrochemical porosification.

32. The method as claimed in claim 30, wherein forming the functional semiconductor body comprises:
applying a third semiconductor layer on the second layer, in which at least one active layer for emitting light is formed,
forming contact regions on the third semiconductor layer, which contact the active layer for emitting light,
shaping depressions or trenches between non-porosified structures in the first layer therefore providing the semiconductor body configured for emitting light over a non-porosified structure, and
removing the porosified first layer.

33. The method as claimed in claim 32, wherein shaping is performed in such a way that a material is removed as far as the carrier.

34. The method as claimed in claim 30, wherein detaching the semiconductor body from the auxiliary carrier comprises detaching the semiconductor body suitable for emitting light from non-porosified structures of the first layer, and wherein detaching is performed by a laser lift-off or a mechanical method.

35. A semiconductor arrangement comprising:
a carrier substrate;
a first doped layer arranged on the carrier substrate and having at least one first region;
a second layer arranged on the first doped layer; and
a functional semiconductor layer sequence arranged on the second layer,
wherein the at least one first region of the first doped layer comprises a porosified semiconductor material having a degree of porosity of at least 20% by volume.

36. The semiconductor arrangement as claimed in claim 35, wherein the first doped layer further comprises at least one second region, wherein the at least one second region of the first layer has a degree of porosity of less than 10% by volume and comprises a doped semiconductor material.

37. The semiconductor arrangement as claimed in claim 36, wherein the at least one second region, after removal of porosified regions, has a diameter which decreases in a direction toward the functional semiconductor layer sequence.

38. The semiconductor arrangement as claimed in claim 35, wherein the functional semiconductor layer sequence comprises an active semiconductor layer sequence suitable for emitting light, wherein the functional semiconductor layer sequence has at least one contact region for contacting the functional semiconductor layer sequence on a side facing away from the first and second layers.

39. The semiconductor arrangement as claimed in claim 35, wherein the second layer has a doping concentration that is lower than the one of an at least one second region of the first layer.

40. The semiconductor arrangement as claimed in claim 35, wherein the functional semiconductor layer sequence has at least one trench which separates regions of the functional semiconductor layer sequence from one another, and wherein each of these regions is arranged over a second region of the first layer.

41. The semiconductor arrangement as claimed in claim 35, wherein a porosified first layer remains on the functional semiconductor layer sequence, and wherein the porosified first layer is optionally an output coupling structure for electromagnetic radiation.

42. The semiconductor arrangement as claimed in claim 35, wherein a concentration of a dopant within the first layer increases from the carrier substrate toward the second layer.
